(19) United States
(12) Patent Application Publication
(10) Pub. No.: US 2011/0065258 A1
(43) Pub. Date: Mar. 17, 2011

(54) METHOD OF PRODUCING BONDED SUBSTRATE

(75) Inventors: Hidehiko OKUDA, Tokyo (JP); Takashi SAKAI, Tokyo (JP)

(73) Assignee: SUMCO CORPORATION, Tokyo (JP)

(21) Appl. No.: 12/877,439

(22) Filed: Sep. 8, 2010

(30) Foreign Application Priority Data
Sep. 11, 2009 (JP) 2009-210335

(51) Int. Cl. H01L 21/18

(52) U.S. Cl. 438/459; 257/E21.087

(57) ABSTRACT

A bonded wafer is thinned from an active layer wafer side, and a thinning stop layer is exposed. Thereafter, the layer is made porous in an HF solution, and then the layer is polished and removed. Thus, the removal of the layer is easy; productivity of substrates is high; no defect is caused due to heat treatment; and evenness in polish amount within a wafer surface can be maintained.

### CROSS-REFERENCE TO RELATED APPLICATIONS

The present application claims priority under 35 U.S.C. §119 of Japanese Application No. 2009-210335 filed on Sep. 11, 2009, the disclosure of which is expressly incorporated by reference herein in its entirety.

### BACKGROUND OF THE INVENTION

1. Field of the Invention

The present invention relates to a method of producing a bonded substrate, specifically a method of producing a bonded substrate requiring thinning of an active layer, such as, for example, a thin-film bonded SOI wafer and a rear-surface irradiation type solid-state image sensing device.

2. Description of Related Art

A bonded SOI wafer, for instance, which is one type of bonded substrates, is generally produced by bonding an active layer wafer formed of silicon and a support substrate wafer formed of silicon having an isolating film in between; and then grinding and polishing the active layer wafer from a rear side thereof, so as to provide an active layer having a desired thickness. As another bonded substrate, a DSB (Direct Silicon Bond) wafer is also developed, in which two wafers are directly bonded without having an isolating film in between, in order to meet demands for miniaturization of devices and low power consumption.

With higher integration and higher speed of semiconductors proposed, the ultra thin and high flat trend is significant in active layers of bonded substrates. In production of rear-surface irradiation type CMOS solid-state image sensing devices, for instance, it is recently demanded that a thickness of an active layer be reduced as thin as 0.3 μm or less, and that surface roughness be as little as 2.0 nm (rms) or less.

As described above, for production of bonded substrates having ultra thin and high flat active layers, a new technology needs to be developed for grinding and polishing active layer wafers in order to obtain active layers having desired flatness and thickness after bonding of wafers. In order to develop a new production technology, it is necessary to consider not only high precision of products, but also production efficiency and cost reduction.

WO2005/074033 is conventionally known as a method of producing such a bonded substrate. In the method, an active layer wafer having an oxygen ion-implanted layer and a support substrate wafer are first bonded. Subsequently, while an alkaline polishing solution is supplied, the bonded wafer is ground and polished (etched) from the active layer wafer side to the ion-implanted layer, and thereby the ion-implanted layer is exposed. The bonded wafer is then heat-treated, and thereby an oxide film is formed on an exposed surface of the ion-implanted layer. Subsequently, an HF solution is used to etch the ion-implanted layer along with the oxide film. Thereby, thinning of the active layer and evenness in film thickness can be achieved.

In the conventional method disclosed in WO2005/074033, however, the bonded wafer is thinned from the active layer wafer side, and thus the ion-implanted layer is exposed; the bonded wafer is then heat-treated, and thus the oxide film (sacrifice oxide film) is formed on a front surface side of the ion-implanted layer; and subsequently, the bonded wafer is immersed in the HF solution, and thus the ion-implanted film is etched and removed along with the oxide film. Accordingly, removal of the ion-implanted layer is complicated, and the production efficiency of bonded substrates is deteriorated.

To produce a rear-surface irradiation type CMOS solid-state image sensing device using the technology of WO2005/074033, for example, oxygen is first ion-implanted in the active layer wafer, and thereby the ion-implanted layer is provided. Then, an epitaxial film is formed on the front surface of the active layer. After a device is formed on the epitaxial film, the active layer wafer and a support substrate wafer are bonded, and thereby a bonded wafer is provided. Subsequently, the active layer wafer excluding the active layer and the ion-implanted layer are removed in the above-described thinning treatment. The epitaxial film including the device exists, however, beneath (rear side) the ion-implanted layer of the bonded wafer. It is thus impossible to employ the method of removing the ion-implanted layer in high temperature oxidation treatment (sacrifice oxidation) of the technology of WO2005/074033, since the device in the epitaxial film is deteriorated at the time of high temperature oxidation treatment.

As a result of diligent research, the inventors focused on polishing without above-described sacrifice oxidation, as a method of removing the ion-implanted layer (thinning stop layer) from the bonded wafer. Specifically, the inventors have found that developing a method of removing the ion-implanted layer mainly based on polishing solves all the problems above, and thus completed the present invention.

When the ion-implanted layer is removed only by polishing, however, a polish amount of the ion-implanted layer might be uneven within a wafer surface, due to a difference in composition of the ion-implanted layer within the surface. An external peripheral portion is prone to be polished in particular. Consequently, the method cannot meet the recent trend of ultra thinning and high flattening of active layers. It is demanded for rear-surface irradiation type CMOS solid-state image sensing devices, for instance, that the thickness of the active layer be 0.3 μm or less, and that the surface roughness be 2.0 nm (rms) or less.

As a result of further diligent research, the inventors have developed a technology in which an ion-implanted layer (thinning stop layer) exposed due to thinning of the active layer wafer and an HF solution are contacted, such that only a silicon oxide in the ion-implanted layer is etched, and thereby a porous ion-implanted layer is provided which is easy for machining. The inventors have then found that when the porous ion-implanted layer is removed only by the above-described polishing, all problems, including evenness in polish amount within the wafer surface, can be solved, and thus completed the present invention.

### SUMMARY OF THE INVENTION

Specifically, the present invention provides a method of producing a bonded substrate, the method allowing removal of a thinning stop layer without heat treatment, and thus eliminating complication from removal work of the thinning stop layer and increasing production efficiency of a bonded substrate; preventing generation of a defect in a semiconductor device and the like, the defect stemming from the heat treatment; and being capable of polishing the thinning stop layer while maintaining evenness in polish amount within a wafer surface.

The present invention provides a method of producing a bonded substrate including ion-implanting oxygen from a front surface of an active layer wafer formed of silicon, and thereby forming in a front layer of the active layer wafer, a thinning stop layer in which silicon grains and a silicon oxide are mixed, and forming an active layer on a more frontward side of the active layer wafer than the thinning stop layer; bonding thereafter a support substrate wafer formed of silicon directly to the front surface of the active layer or indirectly thereto having an isolating film in between, and thereby providing a bonded wafer; thinning the active layer wafer subsequent to the bonding, from a rear side of the active layer wafer, and thereby exposing the thinning stop layer; immersing the bonded wafer in an HF solution subsequently and removing the silicon oxide in the exposed thinning stop layer, and thereby causing the thinning stop layer to be porous; and then polishing and removing the porous thinning stop layer.

According to the present invention, the active layer wafer and the support substrate wafer are bonded, the active layer wafer including the thinning stop layer formed by ion-implanting oxygen. A bonded substrate is produced from the obtained bonded wafer, the bonded substrate being provided with the active layer having a predetermined thickness. In the process, the active layer wafer (bonded wafer) is first thinned from the rear side of the active layer wafer, and thereby exposing the thinning stop layer. Then, the bonded wafer is immersed in the HF solution, and only the silicon oxide (SiO₂ or the like) in the thinning stop layer is etched. Thereby, the thinning stop layer is provided in a porous form, which is easily machined. Subsequently, the porous thinning stop layer is polished and removed.

Thus, conventional heat treatment for sacrifice oxidization is unnecessary for removal of the thinning stop layer. Accordingly, complication of the work is eliminated, and the production efficiency of bonded substrates can be increased. In addition, providing the porous thinning stop layer allows the thinning stop layer to be removed by polishing while evenness in polish amount is maintained within a wafer surface, compared with a case in which a non-porous thinning stop layer is polished. As a result, the film thickness of the active layer can further be even. Furthermore, unlike the conventional method in which high temperature oxidation treatment is performed to sacrifice-oxidize the thinning stop layer, the thinning stop layer can be removed with a high degree of accuracy. The method of the present invention can thus be applied to a production process of rear-surface irradiation type solid-state image sensing devices.

Examples of the bonded substrate may include a bonded SOI substrate, a rear-surface irradiation type solid-state image sensing device, and the like. As the solid-state image sensing device, a CMOS type may be employed, for example. Alternatively, a CCD type may be employed. The solid-state image sensing device herein has a pixel separation region of a shooting region, an epitaxial film provided with a semiconductor well region and a photodiode, and a multilayer wiring layer. Examples of the active layer wafer and the support substrate wafer may include a monocrystalline silicon wafer, a polycrystalline silicon wafer, and the like. A thickness of the active layer wafer and the support substrate wafer is 725 to 775 μm, for instance. A P-type dopant (B and the like) or an N-type dopant (P, As, Sb, and the like) may be added to the active layer wafer and the support substrate wafer, so as to provide a predetermined resistivity.

Oxygen ion implantation in the front layer of the active layer wafer may be performed in any SIMOX process ion implantation, including a low-energy method (100 keV or less), a low-dose method, and a modified low-dose method. In any method, it is preferable that an oxygen ion implantation amount be 25 to 50% of that in a corresponding SIMOX process. A heating temperature of the active layer wafer at the time of oxygen ion implantation is, for example, 200° C. to 600° C. When the temperature is less than 200° C., a significant oxygen implantation damage remains in the front layer of the active layer wafer. When the temperature exceeds 600° C., a degassing amount from an ion implantation device increases. An oxygen implantation energy is 20 to 220 keV. When the energy is less than 20 keV, a surface defect of the active layer wafer is greater. When the energy exceeds 220 keV, a commercially-available ion implantation device is insufficient, and a special large implantation machine having a large ion implantation energy is required.

The oxygen ion implantation amount is 1.0×10¹⁶ atoms/cm² to 1.5×10¹⁷ atoms/cm². When the amount is less than 1.0×10¹⁶ atoms/cm², the thinning stop layer cannot sufficiently function as an end point detector at a time of thinning treatment of the active layer wafer. When the amount exceeds 1.5×10¹⁷ atoms/cm², a time for oxygen ion implantation in the front layer of the active layer wafer is extended, and thus productivity of bonded substrates is reduced and cost increase is incurred. A preferable oxygen ion implantation amount is 6.5×10¹⁶ atoms/cm² to 1.3×10¹⁷ atoms/cm². Within the range, the productivity of bonded substrates is not extremely reduced, and a further advantageous effect can be obtained in which an end point detecting layer can be formed. An oxygen ion implantation depth is 0.05 to 0.5 μm. Oxygen ion implantation in the front layer of the active layer wafer may be performed only once or separately for a plurality of times. Further, oxygen ions may be implanted at a plurality of implantation energies.

The thinning stop layer refers to an incomplete silicon oxide film (incompletely implanted oxide film), which has a silicon oxide and silicon grains mixed at a predetermined proportion and is implanted in the front layer of the active layer wafer, the silicon oxide including a deposited oxide, a zonal oxide, and the like formed of SiOₓ, including SiO₂, the silicon grains being silicon in the active layer wafer granulated due to oxygen ion implantation. The incomplete silicon oxide film refers to a state in which a silicon oxide film is formed discontinuously (intermittently) in an entire region of the thinning stop layer.

A thickness of the thinning stop layer is 0.05 to 0.5 μm. When the thickness is less than 0.05 μm, the thinning stop layer cannot sufficiently function as the end point detector at the time of thinning treatment of the active layer wafer. When the thickness exceeds 0.5 μm, the oxygen ion implantation time is extended, thus the productivity of bonded substrates is reduced and the cost increase is incurred. The “more front side of the active layer wafer than the thinning stop layer” refers to a portion between the thinning stop layer and the wafer front surface (active layer) in the front layer of the active layer wafer. A thickness of the active layer is 0.05 to 0.5 μm, which corresponds to the oxygen ion implantation depth. The implantation depth may appropriately be changed according to requirements for a produced device.

When the active layer wafer and the support substrate wafer are bonded, the support substrate wafer may directly be bonded on the front surface of the active layer. Alternatively, the support substrate wafer may indirectly be bonded on front surface of the active layer, having the isolating film in between. The wafer indirectly bonded having the isolating film in between is provided as a SOI wafer through post-processes. A silicon wafer composite body directly bonded with no isolating film is provided as a DSB wafer. As the isolating film, an oxidation layer (SiO₂), a nitrided layer (Si₃N₄), and the like may be employed. Examples of a method of forming the isolating film may include a method in which at least one of the active layer wafer and the support substrate silicon wafer is heat-oxidized or heat-nitrided in a pre-process of bonding, and a method in which a SiO₂ layer or a Si₃N₄ layer is formed in a CVD method. The isolating film may be formed either before or after the thinning stop layer is formed on the active layer wafer.

Examples of a method of bonding the active layer wafer and the support substrate wafer may include room temperature bonding, vacuum bonding, plasma bonding, and the like. After bonding, the bonded wafer may be inserted in a heat oxidation furnace for bonding heat treatment, so as to increase bonding strength. A heating temperature for the bonding heat treatment is 800° C. or higher, for example, 1,100° C. in case of high temperature heat treatment. A time for the bonding heat treatment is approximately 2 hours in case of high temperature heat treatment. Oxygen and the like is used as atmosphere gas in the heat oxidation furnace. Example of a method of thinning the active layer wafer may include grinding and polishing. In grinding, the rear surface of the active layer wafer (opposite surface to the bonded surface) is ground by a #800 resinoid grinding stone (abrasive grain size of 15 to 25 μm), for instance. The active layer wafer may be left unground after grinding for 1 to 10 μm, for instance, up to the thinning stop layer. In this case, the portion remaining after grinding of the active layer wafer may be removed by polishing using a known polisher. In place of polishing, etching may be employed for removal.

The HF solution may have an HF concentration of 1 to 50 mass %, for example. A time to immerse the bonded wafer in the HF solution is, for example, 1 to 60 minutes. A temperature of the HF solution is 20 to 30° C. The phrase “causing the thinning stop layer to be porous” refers to that the thinning stop layer is made porous like a sponge, since, of the silicon oxide and silicon grains that constitute the thinning stop layer, the silicon oxide is melted out by the HF solution, the silicon oxide including a deposited oxide, a zonal oxide, and the like formed of SiOₓ, including SiO₂, the silicon grains being silicon in the active layer wafer granulated due to oxygen ion implantation.

The porous thinning stop layer may be polished by using a variety of polishers. A single-wafer or batch type polisher may be employed, for example, which is provided with a polishing platen having a polishing cloth on a front surface and a polishing head holding a bonded wafer and pressuring a polished surface of the bonded wafer to the polishing cloth, and performs polishing while a polishing solution is supplied. Particularly, a single-wafer type polisher is preferable, which polishes bonded wafers one by one. A polishing rate of the porous thinning stop layer is 0.01 to 0.1 μm/minute. When the rate is less than 0.01 μm/minute, the stop layer cannot be removed completely. When the rate exceeds 0.1 μm/minute, it is highly likely to polish beyond the stop layer to the support substrate side. A preferable polishing rate of the thinning stop layer is 0.02 to 0.05 μm/minute. A polish amount of the thinning stop layer may appropriately be changed according to the thinning stop layer thickness.

It is preferable to employ mechanochemical polishing using an alkaline polishing solution. Using the alkaline polishing solution more likely causes a difference in etching rate between silicon and the SiO₂ layer (thinning stop layer), and thus the thinning stop layer effectively functions as a polishing stop layer. Examples of the alkaline polishing solution may include inorganic alkali (KOH, NaOH, and the like), organic alkali having an amine as a main component (piperazine, ethylenediamine, and the like). The alkali polishing solution may include free abrasive grains. Silica (colloidal silica particles), diamond, and the like may be employed as free abrasive grains.

An average grain size of free abrasive grains is, for example, 0.03 to 0.08 μm. A concentration of abrasive grains in the alkali polishing solution is 10 mass % or less, preferably 0.1 mass % or less, so as to prevent scratches from being caused on a wafer by the abrasive grains, to ensure pH stability of the alkaline polishing solution, and to prevent condensation. As the polishing cloth, it is preferable to use a polishing cloth formed of an unwoven fabric impregnated with urethane and wet-foamed, since the difference in etching rate is much more likely generated. In a polishing process, it is necessary to detect that a portion of the polished surface reaches the thinning stop layer, based on the difference in etching rate between the silicon and SiO₂ layer. For detection, for example, polishing may be performed while polishing processing torque is measured. Examples of a method of detecting a change of polishing processing torque may include detecting a change in current value of an electric motor as a rotation driving force of the polishing platen of the polisher; detecting a change in torsion value generated at a rotation axis of the polishing platen, and detecting a change in vibration value of the polishing platen.

In the present invention, it is preferable that the HF concentration of the HF solution be 1 to 50 mass % and that the immersion time of the bonded wafer in the HF solution be 1 to 60 minutes.

When the HF concentration of the HF solution is less than 1 mass %, the HF concentration is too low, and thus the thinning stop layer is not sufficiently porous. When the HF concentration exceeds 50 mass %, surface roughness of the wafer is caused. A preferable HF concentration of the HF solution is 5 to 10 mass %. Within the range, the surface roughness is not caused, and the thinning stop layer can be made porous in a relatively short time. When the immersion time of the bonded wafer in the HF solution is less than 1 minute, the immersion time is too short, and thus the thinning stop layer is not sufficiently porous. When the immersion time exceeds 60 minutes, the surface roughness is caused.

In the present invention, it is preferable that the thinning stop layer be polished in mechanochemical polishing, in which a polishing cloth formed of an unwoven fabric impregnated with urethane, which is wet-foamed, and an alkaline polishing solution are used. Thereby, the difference in etching rate due to the alkaline polishing solution is enhanced between the active layer formed of silicon and the porous thinning stop layer. As a result, it is easy to detect an end point of polishing of the thinning stop layer. More specifically, the polishing cloth normally used for finish polishing is applied to polishing of the porous thinning stop layer, which is concurrently rough polishing, in the present invention. Thereby, the difference in etching rate can easily be detected between the silicon and thinning stop layer. A known polishing cloth may be used for the polishing cloth formed of an unwoven fabric impregnated with urethane and wet-foamed.

### BRIEF DESCRIPTION OF THE DRAWINGS

The present invention is further described in the detailed description which follows, in reference to the noted plurality of drawings by way of non-limiting examples of exemplary embodiments of the present invention, in which like reference numerals represent similar parts throughout the several views of the drawings, and wherein:

FIG. 1 is a flow sheet illustrating a method of producing a bonded substrate according to a first embodiment of the present invention.

### DETAILED DESCRIPTION OF PREFERRED EMBODIMENTS

The particulars shown herein are by way of example and for purposes of illustrative discussion of the embodiments of the present invention only and are presented in the cause of providing what is believed to be the most useful and readily understood description of the principles and conceptual aspects of the present invention. In this regard, no attempt is made to show structural details of the present invention in more detail than is necessary for the fundamental understanding of the present invention, the description is taken with the drawings making apparent to those skilled in the art how the forms of the present invention may be embodied in practice.

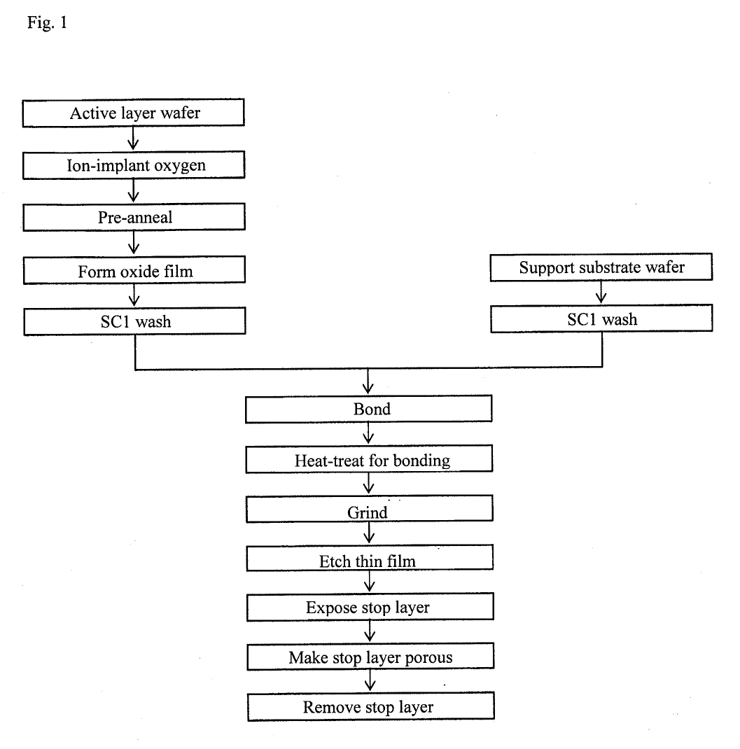

A method of producing a bonded substrate according to a first embodiment of the present invention is explained below, with reference to a flow sheet of FIG. 1. An active layer wafer is first prepared. The active layer wafer is a P⁺ (111) monocrystalline silicon wafer having a diameter of 300 mm and a boron-doped resistivity of 1.0 Ω·cm, the silicon wafer being processed from silicon monocrystal pulled up in a CZ process. Subsequently, oxygen is ion-implanted in the active layer wafer from a wafer front surface, and thereby a thinning stop layer (ion-implanted layer) is provided, which is an incomplete silicon oxide film mixed with silicon grains and a silicon oxide. Specifically, oxygen is ion-implanted from the front surface of the active layer wafer at a wafer temperature of 400° C., an accelerating voltage of 216 keV, and an ion implantation amount of 1.3×10¹⁷ atoms/cm². Thereby, the thinning stop layer having a thickness of 0.15 μm is provided at a depth of 0.5 μm from the front surface of the active layer wafer. Concurrently, an active layer having a thickness of 0.35 μm is provided between the front surface of the active layer wafer and the thinning stop layer.

Then, the active layer wafer is pre-annealed in an argon gas atmosphere for 1 hour at a temperature of 1,200° C. Thereafter, the active layer wafer is further heat-treated in a water-vapor atmosphere for 4 hours at a temperature of 950° C., and thereby a silicon oxide film having a film thickness of 150 nm is provided. Meanwhile, a Fr (100) monocrystalline silicon wafer having a diameter of 300 mm is prepared as a support substrate wafer, the silicon wafer being obtained by processing silicon monocrystal pulled up in the CZ process. Subsequently, the active layer wafer and the support substrate wafer undergo pre-bonding cleaning with an SC 1 cleaning solution.

Thereafter, the front surface of the active layer wafer on the oxygen ion-implanted side and a surface of the support substrate wafer are bonded in plasma bonding, and are then heat-treated for bonding reinforcement in a water-vapor atmosphere for 10 hours at a temperature of 350° C. A bonded wafer is thus provided. The bonded wafer is ground from the active layer wafer side, using a #300 vitrified grinding stone, such that 10 μm of a silicon thin film is left from the thinning stop layer. The silicon thin film is then etched in a KOH aqueous solution (80° C.) having a KOH concentration of 35 mass %. Thus, the thinning stop layer is exposed on the bonded wafer.

Subsequently, the bonded wafer having the exposed thinning stop layer is immersed in an HF solution (25° C.) having an HF concentration of 8 mass % for 15 minutes. Then, the silicon oxide in the thinning stop layer is etched, and thus the thinning stop layer is porous. After the etching, the bonded wafer is transferred to a single-wafer type single-side polisher, and then the porous thinning stop layer is polished. Specifically, the thinning stop layer is placed downward; the bonded wafer is fixed to a lower surface of a polishing head; and a polishing cloth is attached to an upper surface of a polishing platen. The polishing cloth used is a suede-type cloth formed of an unwoven fabric impregnated with urethane and wet-foamed. Then, while a polishing solution is supplied to the polishing cloth at a rate of 0.5 liter/minute, the polishing platen is rotated at a rate of 30 rpm, and the polishing head is rotated in a same direction at a rate of 31 rpm; the polishing head is gradually lowered and the thinning stop layer is pressed against the polishing cloth and polished, and thus the thinning stop layer is removed. Thereby, the active layer is exposed, and a bonded substrate having a SOI structure is produced. As the polishing solution, a KOH polishing solution (alkaline polishing solution) is used, the KOH polishing solution being dispersed at a concentration of 0.01 mass % with free abrasive grains formed of silica having an average grain size of 0.05 μm.

With the structure above, conventional heat treatment is unnecessary to remove the thinning stop layer. Complication of the work is thus eliminated, and the production efficiency of bonded substrates can be improved. In addition, the method is applicable to a production process of rear-surface irradiation type solid-state image sensing devices. Further, since the thinning stop layer is porous, the thinning stop layer can be removed with a high degree of accuracy while a polish amount within a wafer surface can be evenly maintained, compared with a case in which a non-porous thinning stop layer of an incomplete oxide film is polished. Furthermore, a suede-type polishing cloth formed of an unwoven fabric impregnated with urethane and wet-foamed, is used to polish and remove the thinning stop layer in mechanochemical polishing, while a KOH polishing solution is supplied. As a result, the difference in etching rate is enhanced due to the KOH polishing solution between the active layer formed of silicon and the porous thinning stop layer, and thus it is easy to detect an end point of polishing of the thinning stop layer.

Tests described below were performed on the bonded wafer according to the first embodiment. Evaluation results are reported with respect to a film thickness of the active layer before and after polishing and evenness in film thickness thereof, and a polish amount of the thinning stop layer and evenness in polish amount thereof.

### Comparative Example 1

A bonded wafer having an exposed thinning stop layer was transferred to a single-wafer type single-side polisher. The thinning stop layer was placed downward, and the bonded wafer was fixed to a lower surface of a polishing head. A polishing cloth (suede-type) formed of an unwoven fabric impregnated with urethane and wet-foamed, was attached to an upper surface of a polishing platen. Then, the polishing head was gradually lowered so as to pressure an etched surface of the active layer wafer. The thinning stop layer was polished for 600 seconds, while the polishing platen was rotated at a rate of 30 rpm, and the polishing head was rotated in a same direction at a rate of 31 rpm. The film thickness of the active layer and evenness in film thickness thereof were evaluated. Based on the results, the polish amount of the thinning stop layer and evenness in the polish amount thereof were also evaluated. The results are shown in Table 1.

TABLE 1

| | | | | Evenness in | | Evenness in | | |
|---|---|---|---|---|---|---|---|---|
| | | | Active layer | active layer | Active layer | active layer | | Evenness |
| | HF | Polish | thickness | film thickness | thickness | film thickness | Polish | in polish |
| | immersion | time | before polish | before polish | after polish | after polish | amount | amount |
| Comparative | No | 600 sec. | 4407 Å | 169 Å | 3851 Å | 1131 Å | 560 Å | 2621 Å |
| example 1 | | | | | | | | |
| Comparative | No | 890 sec. | 4430 Å | 161 Å | 3720 Å | 1614 Å | 701 Å | 3074 Å |
| example 2 | | | | | | | | |
| Test | 8% HF | 600 sec. | 4392 Å | 129 Å | 2542 Å | 327 Å | 1848 Å | 321 Å |
| example 1 | 15 min. | | | | | | | |
| Test | 8% HF | 890 sec. | 4387 Å | 121 Å | 2258 Å | 458 Å | 2153 Å | 466 Å |
| example 2 | 15 min. | | | | | | | |

In the polishing, a KOH polishing solution was supplied to the polishing cloth at a rate of 0.5 liter/minute, the KOH polishing solution being dispersed with free abrasive grains (silica) having an average grain size of 0.05 μm at an abrasive grain concentration of 0.01 mass %. For evaluation of the active layer film thickness before and after polishing the bonded wafer, 120 points within the wafer surface were measured with an ellipsometer (Aset of KLA-Tencor Corporation). The evenness in active layer film thickness was defined based on “maximum value−minimum value” among the measured 120 points within the wafer surface. For evaluation of the evenness in polish amount, polish amounts of the 120 points within the wafer surface were calculated based on differences in active layer thickness before and after polishing, and an average value of the polish amounts were obtained.

### Comparative Example 2

A different bonded wafer having an exposed thinning stop layer was transferred to the single-side polisher. The thinning stop layer of the bonded wafer was polished under conditions same as Comparative Example 1, except that the polishing time was changed to 890 seconds. The results are also shown in Table 1.

### Test Example 1

A different bonded wafer having an exposed thinning stop layer was immersed in an HF solution (25° C.) having an HF concentration of 8 mass % for 15 minutes. Thereby, a silicon oxide in the thinning stop layer was etched, and thus the thinning stop layer was made porous. Thereafter, the thinning stop layer of the bonded wafer was polished under conditions same as Comparative Example 1 (polishing time was 600 seconds). The active layer film thickness after polishing and evenness in active layer film thickness were evaluated. Based on the results, the polish amount of the thinning stop layer and evenness in polish amount of the thinning stop layer were also evaluated. The results are also shown in Table 1.

### Test Example 2

A different bonded wafer having an exposed thinning stop layer was immersed in an HF solution (25° C.) having an HF concentration of 8 mass % for 15 minutes, under conditions same as Text Example 1. Thereby, a silicon oxide in the thinning stop layer was etched, and then the thinning stop layer was made porous. Thereafter, the bonded wafer was transferred to the single-side polisher. The thinning stop layer of the bonded wafer was polished under the conditions same as Text Example 1, except that the polishing time was changed to 890 seconds. The results are also shown in Table 1.

As demonstrated in Table 1, the polish amount was increased and the evenness in polish amount within the wafer surface was increased in Test Examples 1 and 2, in which the porous thinning stop layer was provided after being immersed in the HF solution, regardless of the polishing time of 600 seconds or 890 seconds, compared to Comparative Examples 1 and 2 without immersion in the HF solution. As a result, the active layer film thickness after polishing was reduced, and the evenness in active layer film thickness within the wafer surface after polishing was increased.

Since the present invention can produce a bonded substrate without performing high temperature heat treatment after the active layer wafer and the support substrate wafer are bonded, it is effective in production of rear-surface irradiation type solid-state image sensing devices, for instance, susceptible to heat degradation of devices.

It is noted that the foregoing examples have been provided merely for the purpose of explanation and are in no way to be construed as limiting of the present invention. While the present invention has been described with reference to exemplary embodiments, it is understood that the words which have been used herein are words of description and illustration, rather than words of limitation. Changes may be made, within the purview of the appended claims, as presently stated and as amended, without departing from the scope and spirit of the present invention in its aspects. Although the present invention has been described herein with reference to particular structures, materials and embodiments, the present invention is not intended to be limited to the particulars disclosed herein; rather, the present invention extends to all functionally equivalent structures, methods and uses, such as are within the scope of the appended claims.

The present invention is not limited to the above described embodiments, and various variations and modifications may be possible without departing from the scope of the present invention.

What is claimed is:

1. A method of producing a bonded substrate comprising:
ion-implanting oxygen from a front surface of an active layer wafer formed of silicon, and forming in a front layer of the active layer wafer, a thinning stop layer in which silicon grains and a silicon oxide are mixed, and further forming an active layer on a more frontward side of the active layer wafer than the thinning stop layer;
bonding a support substrate wafer formed of silicon one of directly to the front surface of the active layer and indirectly thereto having an isolating film in between, and providing a bonded wafer;
thinning the active layer wafer subsequent to said bonding, from a rear side of the active layer wafer, and exposing the thinning stop layer;
immersing the bonded wafer in an HF solution and removing the silicon oxide in the exposed thinning stop layer, and causing the thinning stop layer to be porous; and
polishing and removing the porous thinning stop layer.

2. The method of producing a bonded substrate according to claim 1, wherein the HF solution has an HF concentration of 1 to 50 mass % and an immersion time of the bonded wafer in the HF solution is 1 to 60 minutes.

3. The method of producing a bonded substrate according to claim 1, wherein the polishing of the thinning stop layer is mechanochemical polishing, in which a polishing cloth formed of an unwoven fabric impregnated with urethane, which is wet-foamed, and an alkaline polishing solution are used.

4. The method of producing a bonded substrate according to claim 2, wherein the polishing of the thinning stop layer is mechanochemical polishing, in which a polishing cloth formed of an unwoven fabric impregnated with urethane, which is wet-foamed, and an alkaline polishing solution are used.
